(19) United States
(12) Patent Application Publication
(10) Pub. No.: US 2010/0032498 A1
(43) Pub. Date: Feb. 11, 2010

(54) Apparatus and Method for Identifying and Marking Bales of Bulk Material such as Fodder Bales that have Particular Characteristics

(75) Inventors: RICHARD KINGSWOOD KELLY, THEBARTON (AU); RAYMOND CHARLES WILLIAMS, THEBARTON (AU)

Correspondence Address: WEINER & BURT, P.C., 635 N US-23, POB 186, HARRISVILLE, MI, 48740, US

(73) Assignee: SIPCO PTY LTD, ADELAIDE (AU)

(21) Appl. No.: 12/187,408

(22) Filed: Aug. 7, 2008

(51) Int. Cl. B05B 13/00; B05B 15/00; G01R 27/26

(52) U.S. Cl. 239/274; 239/289; 73/75; 324/689

(57) ABSTRACT

An apparatus for marking a bale of bulk material, such as a bale of fodder having a frame defining a gap through which passes the baled material. A marking system, typically comprising of at least one spray can operates to mark the bale. One specific use of the invention is where the moisture of a bale of fodder is measured and if it exceeds a predetermined level the bale is sprayed with a can of spray paint to indicate to a person that the moisture content of the bale is higher then a set threshold.

An apparatus and method for identifying and marking bales of bulk material such as fodder bales that have particular characteristics.

### BACKGROUND OF THE INVENTION

In the process of making bales of fodder, both hay and silage, the properties of the fodder are often measured using real time measuring instruments. Typically, the bales are ejected from the baling machine and left in the field for other machinery to pick up and transport away. The measurement of various parameters may be critically important in further handling of the bales. For example, bales of hay that have too much moisture are susceptible to spontaneously combust. In a confined space, such as hay shed, truck or even a ship, this can have catastrophic consequences. For this reason it is important to be able not only to measure bales with predetermined properties but once measured also be able to identify or mark them so that other people can identify bales with specific properties.

Thus when a bale that falls within certain predetermined characteristics has been measured and marked, the person picking up the bale can then identify it and do something different, such as keeping the bale separate from others if there is a danger of combustibility.

The features of this invention have particular application to fodder but are not specifically limited in their broadest application to simply fodder, and can in a broadest sense apply to any baled bulk material, including organic material.

It is an object of the present invention to provide an apparatus and method that may be used with balers or separately that can measure a parameter of the product, and to mark such a product to allow a person to differentiate between bales having different values of the measured or observed parameter.

It is a further object of the present invention to provide an apparatus and system that can measure the moisture content of fodder bales and that can mark those bales whose moisture content is greater or less than a predetermined value.

It is still a further object of the present invention to allow an operator of the apparatus to mark bales according to other characteristics of the bale, such as contamination of the fodder by weeds.

### SUMMARY OF THE INVENTION

In a broad aspect the invention could be said to reside in an apparatus for measuring and marking a bale of fodder said apparatus including:

a microwave transmitting antenna and a microwave receiving antenna defining a gap therein between, said gap wide enough to accommodate a fodder bale to pass therethrough;
an operating means adapted to control the transmitting antenna to transmit microwave signals though the bale, said signals received by the receiving antenna and transmitted back to the control means where they are processed and compared to signals received by the receiving antenna that have passed through air, such that if said difference is greater then a pre-determined amount said operating means operates a visual marking system to mark that bale.

The marking system preferentially includes a can of spray paint housed in a cradle and having a spray nozzle that can be actuated by the operating system. Typically the actuation of the spay nozzle is achieved by a solenoid controlled by the operating system.

However, the operation of the spray nozzle can be achieved by an operator who, for example, receives an alert signal that a particular bale being measured has certain properties so that the operator can choose if they mark the bale or not.

In preference the spray can is housed in a cradle having a spring loaded base to hold the can in place, the spring force of which exceeds the force the solenoid is required to apply to the nozzle to operate the spray action.

In preference the operating system controls both the length of the time the nozzle is activated as well as the length of time before the nozzle can be activated again.

In preference said marking system may have multiple cans to mark the bale on either side.

In preference there may be adjoining spray cans with different colours that indicated measurements of different parameters.

In a yet further form of the invention there is proposed an apparatus for marking a bale of bulk material said apparatus including:

a frame defining a gap therein between, said gap wide enough to accommodate the bale to pass therethrough; and
a marking system to mark that bale.

### BRIEF DESCRIPTION OF THE DRAWINGS

The accompanying drawings, which are incorporated in and constitute a part of this specification, illustrate several implementations of the invention and, together with the description, serve to explain the advantages and principles of the invention. In the drawings:

FIG. 1 is a perspective view of an embodiment of the present invention just before measuring a parameter of a bale;

FIG. 2 is a perspective view as in FIG. 1 but when measuring the parameter of a bale;

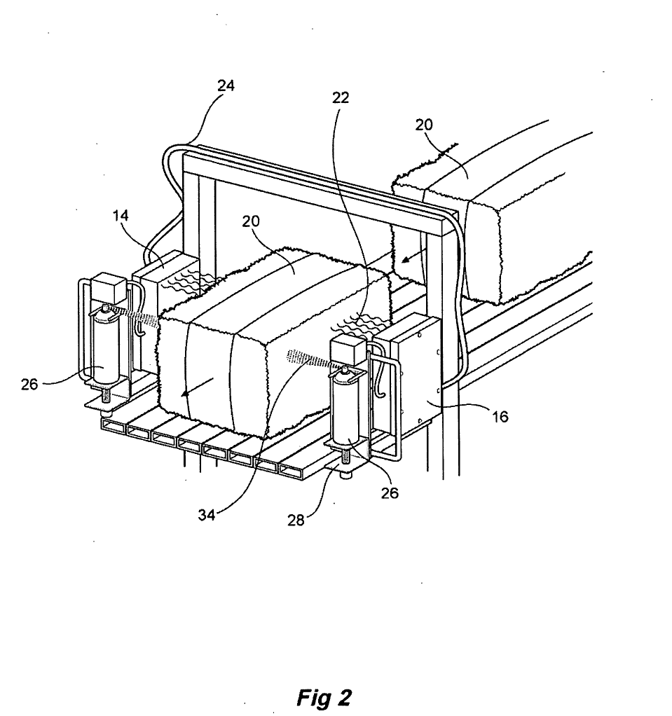

FIG. 3 is a close up view of the bale marking system according to the present invention; and

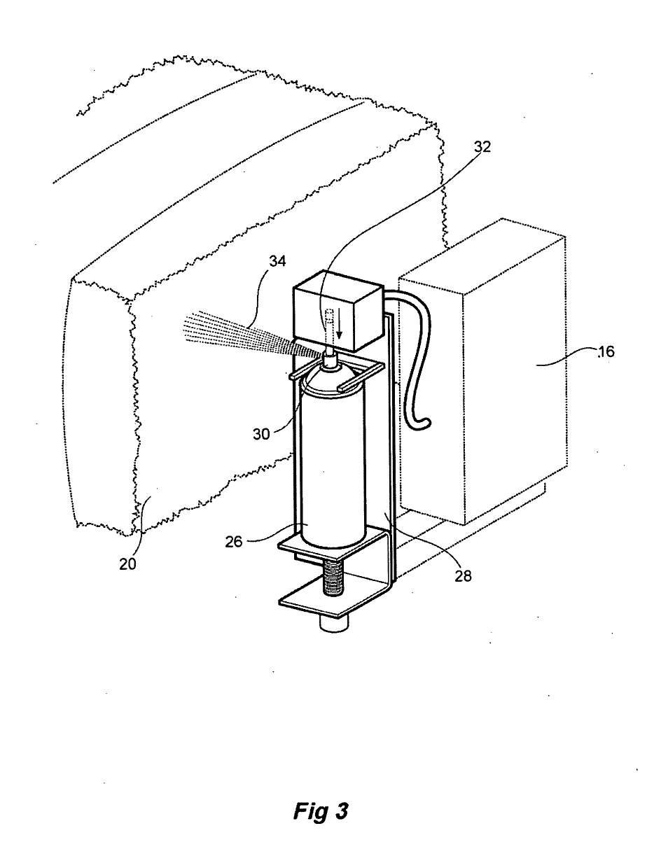

FIG. 4 illustrates the present invention when having multiple marking systems.

### DESCRIPTION OF THE PREFERRED EMBODIMENTS

The following detailed description of the invention refers to the accompanying drawings. Although the description includes exemplary embodiments, other embodiments are possible, and changes may be made to the embodiments described without departing from the spirit and scope of the invention. Wherever possible, the same reference numbers will be used throughout the drawings and the following description to refer to the same and like parts. Dimensions of certain of the parts shown in the drawings may have been modified and/or exaggerated for the purposes of clarity or illustration.

The apparatus of the present invention uses microwave techniques to measure the moisture content of the fodder in the bale as it emerges from the baler. The instrument measures the velocity of the microwaves and the amount of microwave energy absorbed through the bale of fodder. The velocity of microwaves through air is very close to the velocity of light through space, and the velocity of microwaves through dry fodder is slightly less. However, the velocity of microwaves in water is considerably slower than that in dry fodder. The difference in this velocity or speed is attributed to the dielectric constant (relative permittivity).

The dielectric constant for air is close to 1, for dry fibrous material with no air inclusions it is closer to 4 while for pure water it is approximately 80. Similarly, the amount of microwave energy absorbed in air is less than dry fodder and in dry fodder is much less than in water. Thus if measured correctly, these measurements can be a very sensitive method of measuring moisture in the bale of fodder.

Illustrated in the Figures is the apparatus 10 adapted to measure the moisture content of individual bales passing through it and to mark those bales whose moisture content is above or within certain parameters. The apparatus includes a frame 12 supporting on one side transmitting antenna 14 and on the other side receiving antenna 16 defining a gap 18. The antennas are typically some 200 mm wide and sample that footprint of the bale as it passes by the antennas. Bales of hay 20 either from a bale maker or even individually fed from a storage place pass though the gap 18, typically on a conveyor or by being pushed by bales as they are being made.

The transmitting antenna is an active antenna and contains microwave electronics to generate and transmit a beam 22 of microwave energy into the bale 20 and to receive and analyse the signal retuned from the passive receiving antenna 16 on the opposite side of the bale which collects the microwave energy which has not been absorbed by the bale.

A microwave cable 24 that is typically run through a flexible steel conduit carries the collected microwave signal from the receiving antenna back to the electronics in the transmitting antenna for comparison with the originally transmitted signal. The microwave cable should be enclosed in the conduit given that the sampling rate is in the Pico-seconds range and excessive cable movement can cause errors. The conduit thus is securely tied or clamped to the frame 12 to prevent any movement. The microwave cable 24 consists of an inner copper conductor surrounded by a dielectric material. Excessive bending of the cable can damage the dielectric and may cause inaccuracies in the moisture reading.

The measured information may be displayed on a display (not shown) as well as received using well known means. It is not intended to discuss these items in more detail since they are well known engineering principles.

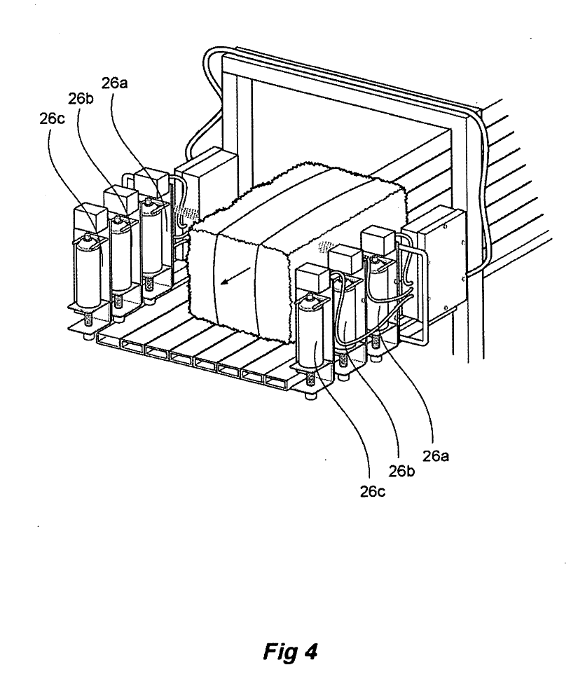

Once the apparatus has detected that the amount of moisture in a bale exceeds a predetermined threshold the system operates a marking system. The marking is accomplished using commonly available paint spray cans 26 that are housed adjacent each of the transmitting and receiving antennas in a cradle 28. The spray nozzle 30 of the spray can is abutted by a solenoid 32 that when energized presses downwards on the nozzle 30 causing a spray of paint 34 to be emitted and sprayed onto the side of the bale 20. The marking system is unique and yet simple in that it uses well known spray cans. The further advantage of this is that different colours may indeed be used to indicate different parameters of the bale. For example, green may be used to indicate too much moisture content, blue to indicate that the fodder is infested with a portion of weeds and other colours yet again may be used to indicate a different type of fodder or indeed fodder collected from different areas. The use of multiple spray cans is illustrated in FIG. 4 where there are now three sets of spray cans 26a, 26b and 26c.

The cradle 28 includes an adjusting means that helps to lock the can into place and yet allows for easy replacement when the can is empty or when a different colour wants to be used. The cradle includes a spring-loaded base to hold the can in place, the spring force of which exceeds the force the solenoid is required to apply to the nozzle to operate the spray action.

Although not shown it is to be understood that the present apparatus may have multiple marking systems so that bales may be marked according to two or more parameters being measured.

During operation of the solenoid it is generally desirable to have a fixed duration spray time followed by a predetermined dead time. This timing arrangement has several advantages. First, it makes sure that the spray time is long enough to make a clearly visible mark, but short enough not to over spray the bale. The dead time ensures there are a series of smaller marks rather than a long line of spray along a bale which is out of specification for its entire length. Using an electrical solenoid enables these times to be easily controlled. The forced dead time also allows the use of a more powerful solenoid whose duty cycle would not allow continuous operation at the full voltage of the implement (typically 12 to 14 Volts) that is found on agricultural machinery.

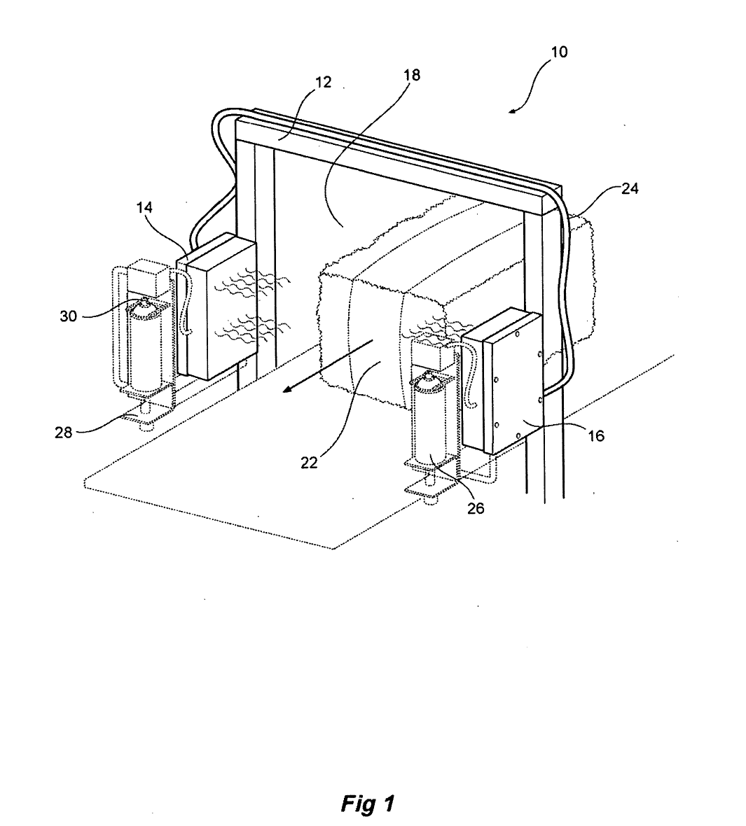

When the apparatus is first used it is calibrated without any bales being between the transmitting and receiving antenna (illustrated in FIG. 1). The entire microwave signals are generated using crystal locked frequency synthesisers that eliminates maintenance or the requirement to check operating frequencies for optimum moisture measurement performance.

In use, when the first bale is passing through the apparatus, the measurement of the parameters does not begin until the leading edge of the bale is typically some 300 mm or a foot forward from the footprint of the antennas. In normal situations this will only apply to the first bale out and successive bales generally abut the preceding bale with no gap between them. Like any electromagnetic signal the microwave signal will always take the easy path if it is available, so, if the readings are taken too close to the ends of the bale, the signal may go around the bale rather than through it, or some other unpredictable “end effects” may occur.

The reader will now appreciate the simplicity and the elegance of the present invention in that it provides an easy method of marking bales whose parameters are within pre-determined criteria and where another person can easily recognise a bale that has been marked.

However, it is to be clearly understood that the present invention may be used without any measuring capability—that is—the invention may be said to reside in just a marking system for bales. It may be automatic, so as to mark every bale that passes through it, or it may be operable by a person who can select which bales to mark.

Further advantages and improvements may very well be made to the present invention without deviating from its scope. Although the invention has been shown and described in what is conceived to be the most practical and preferred embodiment, it is recognized that departures may be made therefrom within the scope and spirit of the invention, which is not to be limited to the details disclosed herein but is to be accorded the full scope of the claims so as to embrace any and all equivalent devices and apparatus.

In any claims that follow and in the summary of the invention, except where the context requires otherwise due to express language or necessary implication, the word “comprising” is used in the sense of “including”, i.e. the features specified may be associated with further features in various embodiments of the invention.

1. An apparatus for marking a bale of bulk material said apparatus including:
a frame defining a gap therein between, said gap wide enough to accommodate the bale to pass therethrough; and
a marking system to mark that bale.

2. An apparatus for measuring and marking a bale of fodder said apparatus including:
a microwave transmitting antenna and a microwave receiving antenna defining a gap therein between, said gap wide enough to accommodate a fodder bale to pass therethrough;
an operating means adapted to control the transmitting antenna to transmit microwave signals though the bale, said signals received by the receiving antenna and transmitted back to the control means where they are processed and compared to signals received by the receiving antenna that have passed through air, such that if said difference is greater then a predetermined amount said operating means operates a visual marking system to mark that bale.

3. An apparatus as in claim 2 wherein said marking system includes a can of spray paint housed in a cradle and having a spray nozzle that can be actuated by the operating system.

4. An apparatus as in claim 3 wherein the actuation of the spray nozzle is achieved by a solenoid controlled by the operating system.

5. An apparatus for measuring and marking a bale of fodder said apparatus including:
a microwave transmitting antenna and a microwave receiving antenna defining a gap therein between, said gap wide enough to accommodate a fodder bale to pass therethrough;
an operating means adapted to control the transmitting antenna to transmit microwave signals though the bale, said signals received by the receiving antenna and transmitted back to the control means where they are processed and compared to signals received by the receiving antenna that have passed through air, such that if said difference is greater then a predetermined amount and operator is given a warning and can manually operate a visual marking system to mark that bale.

6. An apparatus as defined in claim 4 wherein the spray can is housed in a cradle having a spring loaded base to hold the can in place, the spring force of which exceeds the force the solenoid is required to apply to the nozzle to operate the spray action.

7. An apparatus as in claim 2 wherein the operating system controls the length of time the spray nozzle is activated.

8. An apparatus as in claim 3 wherein there are a plurality of spray cans adapted to mark the bale.

9. An apparatus as in claim 8 wherein each spray can is of a different colour.

10. A method for measuring and marking a bale of bulk material, comprising the steps of:
passing a bale of bulk material through a gap defined by a microwave transmitting antenna and a microwave receiving antenna;
controlling said transmitting antenna via operating means to transmit microwave signals through the bale;
receiving said signals received by the receiving antenna; and
transmitting said received signals back to the operating means where they are processed and compared to signals received by the receiving antenna that have passed through air, such that if said difference is greater then a predetermined amount said operating means operates a visual marking system to mark that bale.”
